(19) United States
(12) Patent Application Publication
(10) Pub. No.: US 2015/0262652 A1
(43) Pub. Date: Sep. 17, 2015

(54) ACCESS COUNT DEVICE, MEMORY SYSTEM, AND ACCESS COUNT METHOD

(71) Applicant: NEC Corporation, Tokyo (JP)

(72) Inventor: Kenichi IGARASHI, Tokyo (JP)

(73) Assignee: NEC Corporation

(21) Appl. No.: 14/658,397

(22) Filed: Mar. 16, 2015

(30) Foreign Application Priority Data
Mar. 17, 2014 (JP) 2014-053298

(51) Int. Cl. G11C 11/406; G11C 7/10

(52) U.S. Cl. CPC G11C 11/40622; G11C 7/1027

(57) ABSTRACT

An access count device and the like in a semiconductor memory are disclosed, which count accesses to row addresses in the semiconductor memory with a smaller circuit scale. An access count device includes a row-address storage unit configured to store up to a specific number n (n is an integer equal to or more than 1) of row addresses specified in accesses to memory cells, a counter configured to count an access frequency to each row address stored in the row-address storage unit, and a reset controller configured to notify the row-address storage unit to replace one of the n row addresses with a new row address or discard one of the n row addresses, and also configured to notify the counter to reset an access frequency to the row address replaced or discarded.

This application is based upon and claims the benefit of priority from Japanese Patent Application No. 2014-053298, filed on Mar. 17, 2014, the disclosure of which is incorporated herein in its entirety by reference.

### TECHNICAL FIELD

The present invention relates to an access count device, a memory system, and an access count method.

### BACKGROUND ART

With advances in miniaturization in manufacturing processes of semiconductor memories, in semiconductor memories such as a DRAM (Dynamic Random Access Memory), electric impact such as crosstalk on a word line adjoining an access-concentrated word line increases. This results in a problem that leakage in a capacitor increases and data-garbling occurs in a memory cell connected to the adjoining word line. This problem becomes tangible, for example, when the number of accesses to a given row address reaches hundreds of thousands within a refresh interval in a DRAM having a process rule less than 40 nm (nanometers).

To avoid this problem, the following two countermeasures are generally taken. A first countermeasure is to shorten the refresh cycle. Shortening the refresh cycle enables refresh of the memory cell before data-garbling occurs.

A second countermeasure is to issue, when accesses are concentrated on a row address, a refresh from a memory controller to an adjoining row address to be affected. For example, at each row address, the number of accesses thereto is counted. Then, a refresh is issued to an adjoining row address of a row address the number of accesses to which reaches a threshold-value (e.g., 300,000). Consequently, data-garbling can be prevented from occurring at the adjoining row address.

Patent Literature 1 (Japanese Patent Application Laid-Open No. 9-265784) discloses a technique related to this problem. This related technique is to count accesses to each memory cell by discriminating accesses to data of “0” from accesses to data of “1”, and to then refresh each memory cell at which a count-value exceeds a threshold-value.

Patent Literature 2 (Japanese Patent Application Laid-Open No. 2005-251256) also discloses a technique related to this problem. This technique prevents a charge pumping phenomenon by counting the number of activations of word lines.

However, it is supposed that further advances in miniaturization in manufacturing processes of semiconductor memories in the future increase the impact on the adjoining word line and that data-garbling occurs more easily. Therefore, in order to detect a row address on which accesses are concentrated in a refresh interval, a technique of counting the number of accesses to a row address is important. However, the above general countermeasures and the related technique described in the Patent Literature 1 have the following problems.

The general countermeasure of shortening the refresh cycle causes a problem that power consumption increases due to frequent refreshes. In addition, the general countermeasure also causes a problem that because memory accesses such as a read and a write are interrupted during each refresh, frequent refreshes reduce access performance.

Further, the general countermeasure of issuing a refresh to the adjoining row address needs to provide each row address with a counter in order to count the number of accesses to each row address. For example, a 4-Gb (gigabit) DRAM needs a counter for each of 2¹⁵ row addresses. This causes a problem that a semiconductor-chip area increases.

Further, the technique described in the Patent Literature 1 needs to provide each memory cell with two counters. Therefore, this technique causes the problem that a semiconductor-chip area increases. The technique described in the Patent Literature 2 needs to provide two counters respectively used for columns and rows. Thus, this technique causes the problem that a semiconductor-chip area increases.

These problems of increase in semiconductor-chip area occur not only in the case of providing counters in a DRAM chip but also in the case of providing counters in a memory controller.

### SUMMARY

The present invention is made to solve the above problems. A main object of the present invention is to provide a technique of counting the number of accesses to a row address in a semiconductor memory with a smaller circuit scale.

A first aspect of the present invention is an access count device including: a row-address storage unit that stores up to a specific number n (n is an integer equal to or more than 1) of row addresses specified in accesses to memory cells; a counter that counts an access frequency to each row address stored in the row-address storage unit; and a reset controller that notifies the row-address storage unit to replace one of the n row addresses with a new row address or discard one of the n row addresses, and also that notifies the counter to reset an access frequency to the row address replaced or discarded.

A second aspect of the present invention is a memory system including the above access count device and a memory cell array including the memory cells.

A third aspect of the present invention is an access count method including: storing up to a specific number n (n is an integer equal to or more than 1) of row addresses specified in accesses to memory cells; counting an access frequency to each of the stored row addresses; replacing one of the n row addresses with a new row address or discarding the one of the n row addresses; and resetting the access frequency to the row address replaced or discarded.

According to the present invention, in a semiconductor memory, accesses to row addresses can be counted with a smaller circuit scale.

### BRIEF DESCRIPTION OF THE DRAWINGS

Exemplary features and advantages of the present invention will become apparent from the following detailed description when taken with the accompanying drawings in which:

FIG. 1 is a block diagram illustrating a configuration of a memory system in a first exemplary embodiment of the present invention;

FIG. 2 is a functional block diagram illustrating an access count device in the first exemplary embodiment of the present invention;

FIG. 3 is a flowchart illustrating a reset operation in each refresh interval in the access count device in the first exemplary embodiment of the present invention;

FIG. 4 is a flowchart illustrating a row address storage operation of the access count device in the first exemplary embodiment of the present invention;

FIG. 5 is a flowchart illustrating an intensive-access detection operation of the access count device in the first exemplary embodiment of the present invention;

FIG. 6 is a diagram illustrating an example of a mounting configuration of an access count device in the first exemplary embodiment of the present invention;

FIG. 7 is a block diagram illustrating a memory system serving as a second exemplary embodiment of the present invention;

FIG. 8 is a functional block diagram illustrating an access count device in the second exemplary embodiment of the present invention;

FIG. 9 is a diagram illustrating an example of a mounting configuration of an access count device in the second exemplary embodiment of the present invention; and

FIG. 10 is a diagram illustrating an example of an access count device having a minimum configuration in a third exemplary embodiment of the present invention.

### EXEMPLARY EMBODIMENT

Next, a detailed explanation will be given for exemplary embodiments with reference to the drawings.

### First Exemplary Embodiment

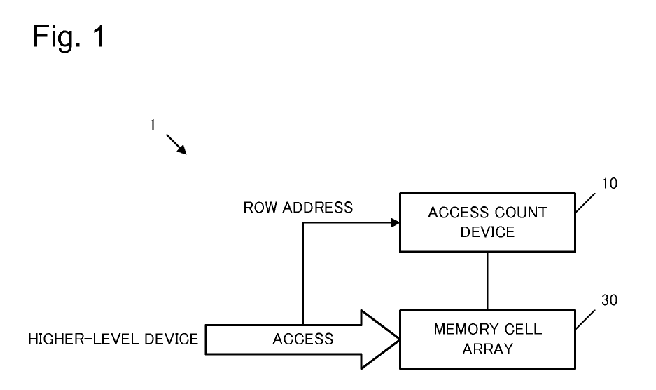

FIG. 1 illustrates a configuration of a memory system 1 in a first exemplary embodiment of the present invention. In FIG. 1, the memory system 1 includes an access count device 10, and a memory cell array 30. The memory cell array 30 includes memory cells each identified, based on a row address and a column address. A higher-level device can access a memory cell by specifying a row address and a column address. The access count device 10 is configured to acquire, as an input, a row address specified in an access to the memory cell array 30 from the higher-level device.

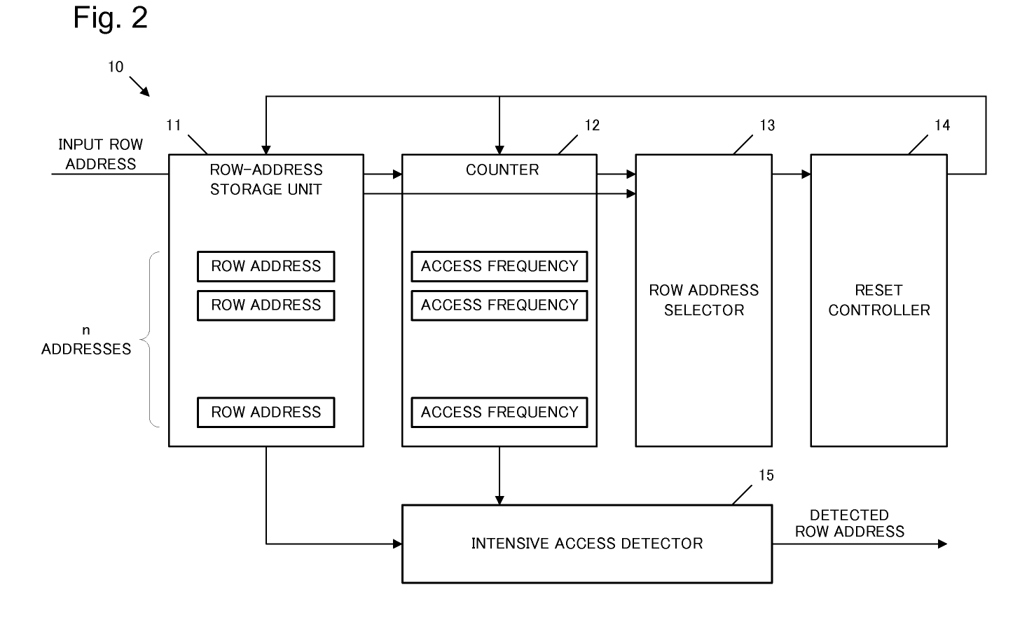

FIG. 2 illustrates a functional block configuration of the access count device 10. In FIG. 2, the access count device 10 includes a row-address storage unit 11, a count unit (counter) 12, a row address selection unit (selector) 13, a reset control unit (controller) 14, and an intensive access detection unit (detector) 15.

The row-address storage unit 11 stores up to a specific (predetermined) number “n” of row addresses specified in accesses to the memory cells. Here, “n” is an integer equal to or larger than 1. In addition, it is desirable that “n” is an integer smaller than the number of row addresses. For example, “n” may be a value based on a refresh interval, an access cycle, and an allowable number of accesses. For example, “n” is obtained from the following equation (1).

n=[(refresh interval)/(access cycle)/(the allowable number of accesses)] equation (1)

Here, [X] represents a maximum integer that does not exceed X. Further, the expression “(refresh interval)/(access cycle)” represents the number of accesses occurring in a refresh interval. Furthermore, the “allowable number of accesses” is a maximum number of allowable accesses to one row address so as not to cause data-garbling at an adjoining row address. The allowable number of accesses is preliminarily determined. The specific number “n” obtained from equation (1) is equivalent to the maximum number of row addresses, the number of accesses to each of which reaches the allowable number of accesses in a refresh interval.

Specifically, for example, it is assumed that the refresh interval is specified to be 64 ms (milliseconds), that the access cycle is specified to be 50 ns (nanoseconds), and that the allowable number of accesses is specified to be 200,000. In this case, the number of accesses occurring in the refresh interval is 64 (ms)/50 (ns)=1,280,000. In this case, the specific number “n” is [1,280,000/200,000]=[6.4]=6. In the present application, “/” represents a division.

The counter 12 counts an access frequency to each row address stored in the row-address storage unit 11. In other words, the counter 12 counts the access frequency to each of up to n row addresses.

The row address selector 13 selects, based on an access-frequency, one of n row addresses stored in the row-address storage unit 11 if an access occurs, in which a new row address other than the n row addresses is specified. For example, the row address selector 13 may select a row address, the access frequency to which meets a specific low frequency condition. The specific low frequency condition may be, for example, that the access-frequency is minimal.

The reset controller 14 notifies the row-address storage unit 11 to store a new row address by replacing the row address selected by the row address selector 13 with the new row address. Further, the reset controller 14 notifies the row-address storage unit 11 to discard a row address, the access frequency to which reaches the above allowable number of accesses. Furthermore, the reset controller 14 notifies the counter 12 to reset the access frequency to the row address replaced or discarded.

Moreover, the reset controller 14 notifies the row-address storage unit 11 to reset (discard) all of the stored row addresses if a refresh is executed after elapse of a time specified as a refresh interval. Further, the reset controller 14 notifies the counter 12 to reset to 0 all counter values held in the counter 12.

The intensive access detector 15 detects a row address the access frequency to which reaches the above allowable number of accesses. For example, the intensive access detector 15 may output the detected low address to the outside. Further, for example, the intensive access detector 15 may issue a refresh to a low address adjoining the detected row address.

An operation of the access count device 10 configured as described above is described hereinafter with reference to the drawings.

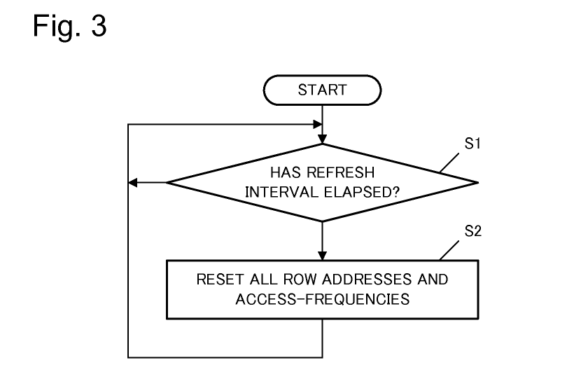

FIG. 3 is a flowchart illustrating a reset operation in each refresh interval in the access count device 10.

First, in step S1, the reset controller 14 decides whether a specific refresh interval has elapsed since the last refresh operation.

If the specific refresh interval has elapsed, in step S2, the reset controller 14 notifies the row-address storage unit 11 to reset (discard) each stored row address. Further, the reset controller 14 notifies the counter 12 to reset to 0 each counter value held by the counter 12.

Thus, the access count device 10 terminates the reset operation in the refresh interval. The reset controller 14 performs the above processing at every refresh interval.

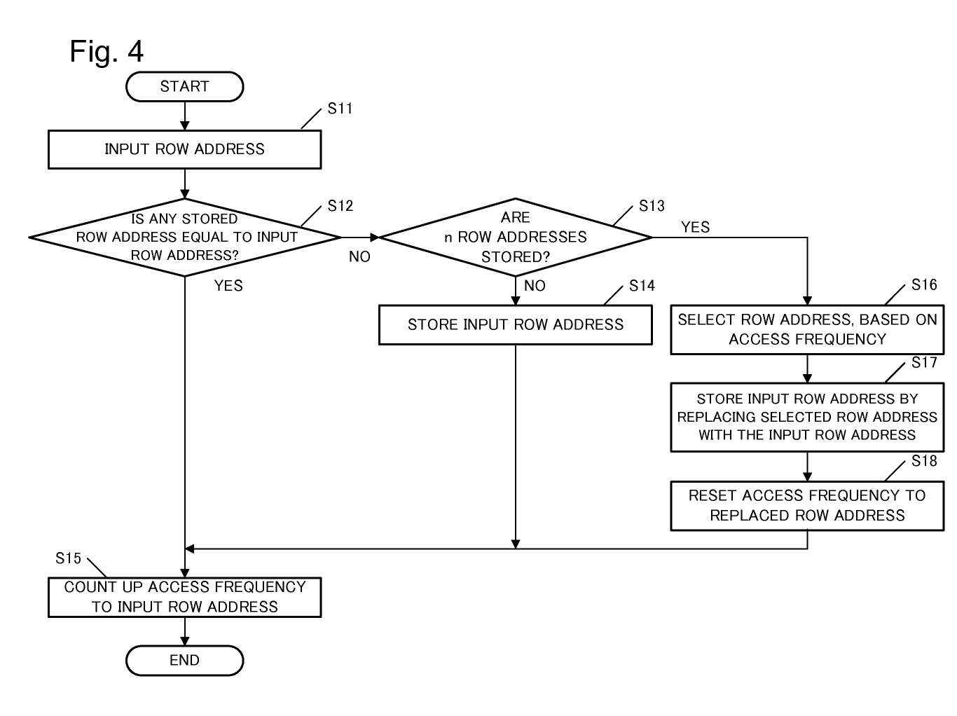

FIG. 4 is a flowchart illustrating an operation of storing an input row address in the access count device 10.

First, in step S11, a row address specified in an access to a memory cell is input to the access count device 10.

A description is given to a case where the input row address is not equal to any of the row addresses already stored in the row-address storage unit 11 (No in step S12), and where the number of row addresses stored in the row-address storage unit 11 is less than n (No in step S13).

In this case, in step S14, the row-address storage unit 11 stores the input row address. Then, in step S15, the counter 12 counts up by 1 (i.e., adds 1 to) the access frequency to the input row address.

Next, a description is given to a case where, meanwhile, the input row address is equal to one of the row addresses already stored in the row-address storage unit 11 (Yes in step S12).

In this case, in step S15, the counter 12 counts up by 1 the access frequency to the input row address.

Next, a description is given to a case where the input row address is not equal to any of the row addresses already stored in the row-address storage unit 11 (No in step S12), and where the number of row addresses stored in the row-address storage unit 11 is n (Yes in step S13).

In this case, in step S16, the row address selector 13 compares n access frequencies stored in the counter 12, and selects, based on a comparison result, one of the row addresses stored in the row-address storage unit 11. For example, as described above, the row address selector 13 may select the row address corresponding to the access frequency satisfying the specific low frequency condition, among the n access frequencies stored in the counter 12.

In step S17, the reset controller 14 notifies the row-address storage unit 11 to store a new row address by replacing the selected row address with the new row address. Based on this notification, the row-address storage unit 11 stores the row address input in step S11.

In step S18, the reset controller 14 notifies the counter 12 to reset the access frequency corresponding to the row address replaced in step S17.

In step S15, the counter 12 counts up by 1 the access frequency to the input row address.

Thus, the access count device 10 terminates the operation of storing the input row address.

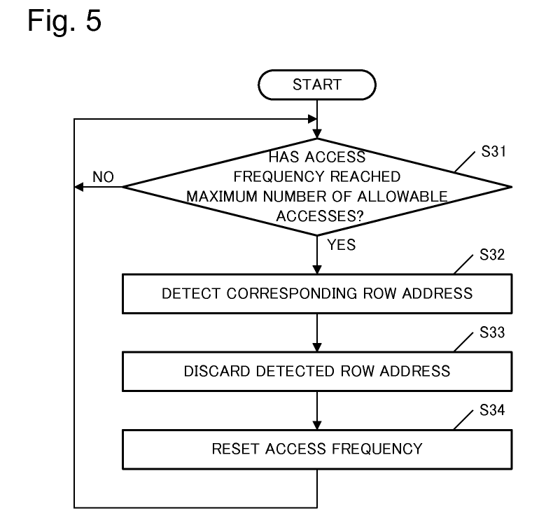

FIG. 5 is a flowchart illustrating an intensive-access detection operation in the access count device 10.

First, in step S31, the intensive access detector 15 decides whether an access frequency counted by the counter 12 reaches the allowable number of accesses. If the intensive access detector 15 decides that the access frequency reaches the allowable number of accesses (Yes in step S31), the intensive access detector 15 detects and outputs a row address corresponding to the access frequency. If the intensive access detector 15 decides that the access frequency does not reach the allowable number of accesses (No in step S31), processing is returned to step S31.

In step S33, the reset controller 14 notifies the row-address storage unit 11 to discard the row address the access frequency to which reaches the allowable number of accesses.

In step S34, the reset controller 14 notifies the counter 12 to reset the access frequency to the row address discarded in step S33.

Thus, the access count device 10 terminates the operation.

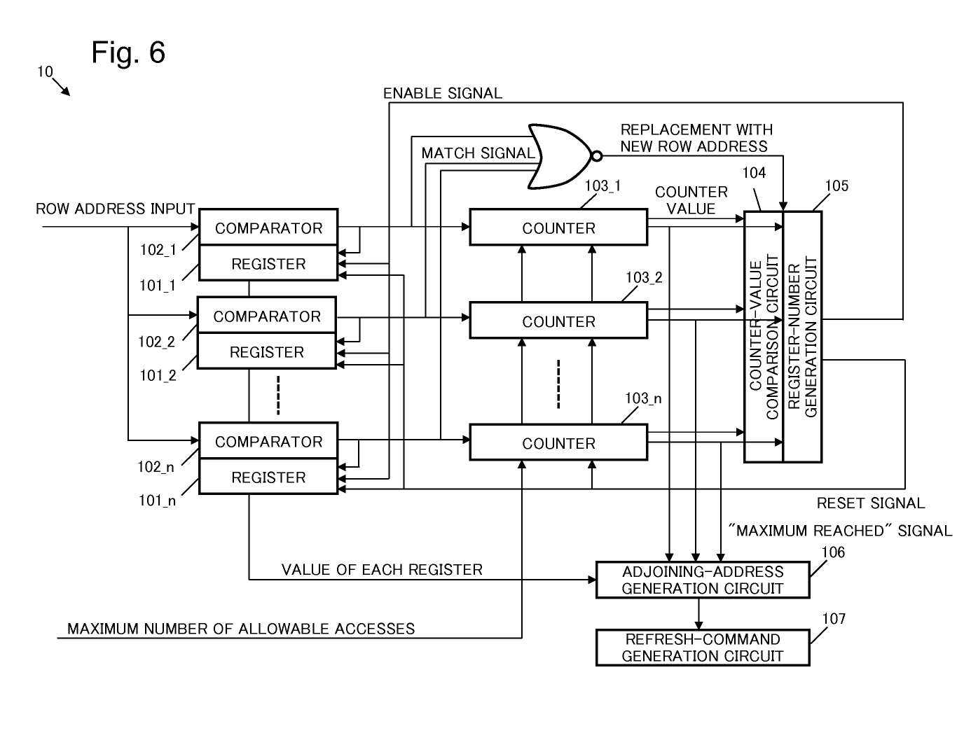

FIG. 6 illustrates an example of a mounting configuration of the access count device 10.

The access count device 10 includes registers 101_1 to 101_n, comparators 102_1 to 102_n, and counters 103_1 to 103_n. Further, the access count device 10 includes a counter-value comparison circuit 104, a register-number generation circuit 105, an adjoining-address generation circuit 106, and a refresh-command generation circuit 107. The registers 101_1 to 101_n and the comparators 102_1 to 102_n configure an exemplary embodiment of the row-address storage unit 11. The counters 103_1 to 103_n configure an exemplary embodiment of the counter 12. Further, the counter-value comparison circuit 104 configures an exemplary embodiment of the row address selector 13. Furthermore, the register-number generation circuit 105 configures an exemplary embodiment of the reset controller 14. Moreover, the adjoining-address generation circuit 106 and the refresh-command generation circuit 107 configure an exemplary embodiment of the intensive access detector 15. Hereinafter, the registers 101_1 to 101_n are sometimes generically described also as a register 101. Further, each register 101 is described also as a register 101_i (“i” is a positive integer (the same applies hereinafter)). Furthermore, hereinafter, the comparators 102_1 to 102_n are sometimes generically described also as a comparator 102. Moreover, each comparator 102 is sometimes described also as a comparator 102_i. Further, hereinafter, the counters 103_1 to 103_n are sometimes generically described also as a counter 103. Moreover, each counter 103 is sometimes described also as a counter 103_i.

The register 101_i stores an externally input row address when an enable signal is input thereto. Further, the register 101_i discards a stored row address when a reset signal is input thereto. Concurrently, the register 101_i outputs a stored row address to the adjoining-address generation circuit 106.

The comparator 102_i compares an externally input row address with a row address stored in the corresponding register 101_i. Then, the comparator 102_i outputs a match/mismatch signal, which represents a match or a mismatch, to the corresponding register 101_i, the corresponding counter 103_i, and the counter-value comparison circuit 104.

The counter 103_i holds a counter value of “0” in a reset state. Further, when a match/mismatch signal representing a match is input to the counter 103_i from the corresponding comparator 102_i, the counter 103_i counts up the counter value by 1. Furthermore, the counter 103_i outputs a counter value to the counter-value comparison circuit 104. Moreover, the counter 103_i is configured such that an allowable number of accesses can externally be set using an input pin or the like. Further, when the counter value reaches the allowable number of accesses, the counter 103_i outputs a “maximum reached” signal to the register-number generation circuit 105 and the adjoining-address generation circuit 106. Furthermore, when a reset signal is input to the counter 103_i, the counter 103_i resets the counter value to 0.

When a match/mismatch signal representing a mismatch is input to the counter-value comparison circuit 104 from each of all of the comparators 102_1 to 102-n, the counter-value comparison circuit 104 compares counter values input from the counters 103_1 to 103_n and selects a minimum counter value. Then, the counter-value comparison circuit 104 outputs to the resister-number generation circuit 105 a selection signal specifying the No. “i” of the counter 103_i from which the selected counter value is input to the counter-value comparison circuit 104.

When the selection signal is input to the resister-number generation circuit 105 from the counter-value comparison circuit 104, the resister-number generation circuit 105 outputs an enable signal to the resister 101_i having the No. “i” specified by the selection signal. Further, the resister-number generation circuit 105 outputs a reset signal to the counter 103_i specified by the selection signal. Furthermore, when a “maximum reached” signal is input to the resister-number generation circuit 105 from the counter 103_i, the resister-number generation circuit 105 outputs a reset signal to each of the corresponding register 101_i and the corresponding counter 103_i.

When a “maximum reached” signal is input to the adjoining-address generation circuit 106 from the counter 103_i, the adjoining-address generation circuit 106 calculates an adjoining row address of a row address using the row address input from the corresponding resister 101_i. Then, the adjoining-address generation circuit 106 outputs the calculated adjoining row address to the refresh-command generation circuit 107.

The refresh-command generation circuit 107 generates a refresh command corresponding to an adjoining row address when the adjoining row address is input to the refresh-command generation circuit 107.

Specific examples of operations of the access count device 10 are described hereinafter. First, a row address storage operation is described in detail with reference to FIG. 4. It is assumed that no row address is stored in each of the registers 101_1 to 101_n at the start of the following specific operations.

First, a row address 1 is assumed to be input to the access count device 10 (step S11). In this case, none of the comparators 102_1 to 102_n store the row address 1. Thus, each of the comparators 102_1 to 102_n outputs a match/mismatch signal representing a mismatch. Then, the counter-value comparison circuit 104 compares counter values input from the counters 103_1 to 103_n and selects a minimum one of the counter values. All of the counter values are 0. Thus, the counter-value comparison circuit 104 is assumed to select one of all of the counter values, which is the counter value input from the counter 103_1. Then, the resister-number generation circuit 105 outputs an enable signal to the resister 101_1 corresponding to the selected counter value, and outputs a reset signal to the corresponding counter 103_1. The output of the enable signal causes the register 101_1 to store the row address 1 (No in step S12, No in step S13, and step S14).

Next, the comparator 102_1 compares the input row address 1 with the row address 1 stored in the register 101_1 and outputs to the counter 103_1 a match/mismatch signal representing a match. This output causes the counter 103_1 to count up the counter value to 1 (step S15).

Next, row addresses 2 to n are assumed to be sequentially input to the access count device 10. In this case, the access count device 10 performs operations substantially similar to the operations in the case of inputting the row address 1 to the access count device 10. Consequently, the registers 101_2 to 101_n store the row addresses 2 to n, respectively. Moreover, each of the counters 103_2 to 103_n stores the counter value of 1.

Next, the row address 2 is assumed to be input to the access count device 10. In this case, the comparator 102_2 compares the input row address 2 with the row address 2 stored in the corresponding register 101_2, and outputs to the corresponding counter 103_2 a match/mismatch signal representing a match. This output causes the counter 103_2 to count up the counter value to 2.

Then, when some of the row addresses 1 to n are sequentially input to the access count device 10, the access count device 10 performs an operation substantially similar to the above operation. By this operation, each of the counters 103_1 to 103_n counts up the counter value thereof and holds the counter value counted up.

Next, a row address_new other than the row addresses 1 to n is assumed to be input to the access count device 10. In this case, none of the comparators 102_1 to 102_n store the row address_new. Therefore, each of the comparators 102_1 to 102_n outputs a match/mismatch signal representing a mismatch. Then, the counter-value comparison circuit 104 compares counter values input from the counters 103_1 to 103_n and selects a minimum one of the counter values. The counter 103_x (1≦x≦n) having the minimum counter value is assumed to be selected (step S16). Then, the register-number generation circuit 105 outputs an enable signal to the register 101_x, and also outputs a reset signal to the counter 103_x. The output of the enable signal causes the register 101_x to store the row address_new by replacing the row address x therewith (step S17). Then, the counter 103_x counts up by 1 the counter value which is already reset to 0 by the reset signal, based on the match/mismatch signal that is input from the comparator 102_x and represents a match (step S18 and step S15).

After that, when row addresses are serially input to the access count device 10, the access count device 10 operates in a manner substantially similar to the above manner.

Next, a specified example of an intensive-access detection operation performed by the access count device 10 is described in detail with reference to FIG. 5. It is assumed that the counter value of the counter 103_y (1≦y≦n) reaches the allowable number of accesses (Yes in step S31). Then, the counter 103_y outputs a “maximum reached” signal to the register-number generation circuit 105 and the adjoining-address generation circuit 106 (step S32).

Because the “maximum reached” signal is input to the adjoining-address generation circuit 106 from the counter 103_y, the adjoining-address generation circuit 106 calculates an adjoining row address of a row address input from the register 101_y, and outputs the calculated adjoining row address to the refresh-command generation circuit 107.

Then, the refresh-command generation circuit 107 generates a refresh command to the input adjoining row address.

Further, because the “maximum reached” signal is input to the register-number generation circuit 105 from the counter 193_y, the register-number generation circuit 105 outputs reset signals to the corresponding register 101_y and the corresponding counter 103_y. The output of the reset signal causes the register 101_y to be empty. Moreover, the output of the reset signal causes the counter value of the counter 103_y to be 0.

Thus, description of the example of the mounting configuration of the access count device 10, and description of the specific example of the operation thereof end.

Next, advantageous effects of the first exemplary embodiment of the present invention are described hereinafter.

The access count device configured as the first exemplary embodiment of the present invention counts the number of accesses to row addresses in a semiconductor memory with a smaller circuit scale. Consequently, the access count device can detect a row address on which accesses are concentrated in a refresh interval, with a smaller circuit scale and without increasing power consumption and reducing access performance.

The reason is that;

the row-address storage unit stores up to the specific number n of row addresses specified in accesses to memory cells;

that the counter counts an access frequency to each row address stored in the row-address storage unit; and

that when an access occurs, which specifies a new row address other than the n row addresses stored in the row-address storage unit, the row address selector selects one of the n row addresses, based on the access frequencies. In addition, the reason is that the reset controller notifies

(1) the row-address storage unit to store a new row address by replacing the row address selected by the row address selector with the new row address,

(2) the row-address storage unit to discard a row address the access frequency to which reaches the allowable number of accesses, and

(3) the counter to reset the access frequency corresponding to the row address replaced or discarded, and

that the intensive access detector detects a row address the access frequency to which reaches the allowable number of accesses.

As described above, the access count device according to the present exemplary embodiment does not need to provide counter circuits of the number of row addresses in the counter, and can efficiently detect each row address the number of accesses to which reaches the allowable number of accesses in a refresh interval only by providing n counter circuits in the counter. Consequently, the present exemplary embodiment can reduce a scale of a circuit for detecting a row address on which accesses are concentrated in a refresh interval. Further, because the present exemplary embodiment does not need to shorten a refresh interval, the present exemplary embodiment can suppress increase of power consumption and reduction in access performance. In addition, the present exemplary embodiment achieves advantageous effects especially in the following case. Note that the present exemplary embodiment particularly achieves advantageous effect in a case in which it is frequent that before the row address storage stores n row addresses (i.e., before n registers are filled with row addresses), the counter value at one of the row addresses reaches the allowable number of accesses and the corresponding row address is reset (i.e., the corresponding register becomes empty).

In the present exemplary embodiment, the access count device may be configured such that the refresh interval, the access cycle, and the allowable number of accesses can externally be set. In this case, the access count device can determine the specific number n, based on the set refresh interval, the set access cycle, and the set allowable number of accesses. Thus, the access count device becomes applicable to semiconductor memories differing in performance from one another. Consequently, for example, in a state in which at most N registers, N comparators, and N counters are mounted in the access count device (N is a positive integer), if the set (determined) number n is less than N, the access count device can utilize unused registers, comparators, and counters for other uses (“n” is the specific number).

### Second Exemplary Embodiment

Next, a second exemplary embodiment of the present invention is described in detail with reference to the drawings. In each drawing referred to in the following description of the present exemplary embodiment, a same component as the component of the first exemplary embodiment is denoted by same reference numeral. In addition, a step in which the second exemplary embodiment operates in a manner similar to the manner of the operation of the first exemplary embodiment is denoted by same reference numeral. Thus, a description of such a component and such a step is omitted.

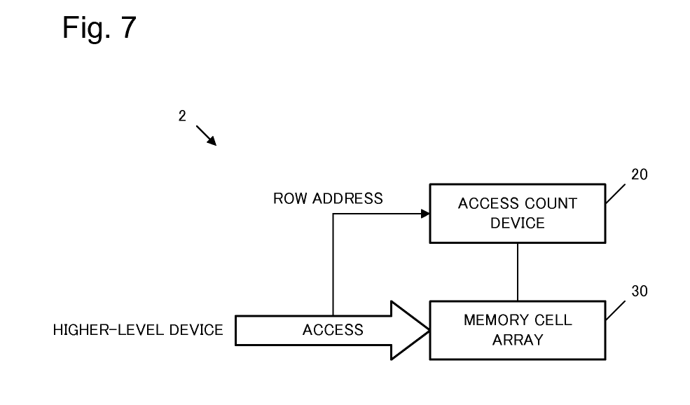

First, FIG. 7 illustrates a configuration of a memory system 2 acting as the second exemplary embodiment of the present invention. In FIG. 7, the memory system 2 differs from the memory system 1 in the first exemplary embodiment of the present invention in being provided with an access count device 20 in place of the access count device 10. The access count device 20 is configured to acquire, as an input, a row address specified in an access to a memory cell array 30 from a higher-level device, similarly to the access count device 10 in the first exemplary embodiment of the present invention.

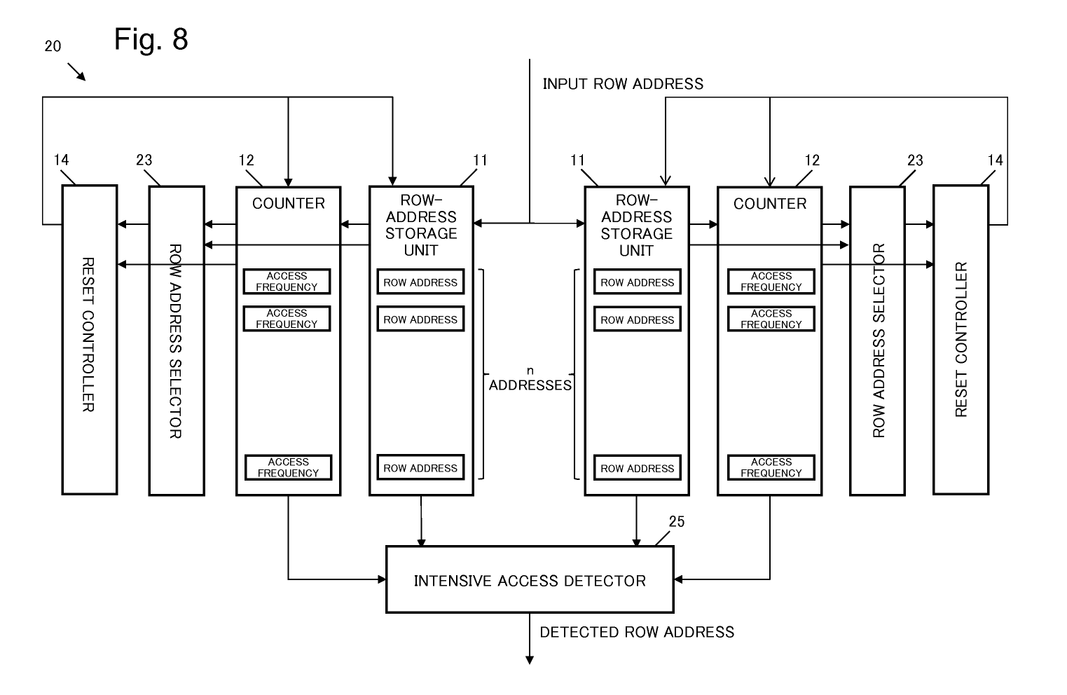

Next, FIG. 8 illustrates a functional block configuration of the access count device 20 in the second exemplary embodiment of the present invention. In FIG. 8, the access count device 20 includes m sets (“m” is an integer equal to or larger than 2) of a combination of a row-address storage unit 11, a count unit (counter) 12, a row-address selection unit (selector) 23, and a reset control unit (controller) 14, and an intensive-access detection unit (detector) 25.

Each of the row-address storage unit 11, the counter 12, and the reset controller 14 is configured similarly to a corresponding functional block in the first exemplary embodiment of the present invention. However, in the second exemplary embodiment, when a row address specified in an access to a memory cell is input to the access count device 20, the row address is input to the row-address storage unit 11 of each set. Although FIG. 8 illustrates an example in which m=2, the number “m” according to the present invention is not limited thereto.

A row address selector 23 is configured substantially similarly to the row address selector 13 in the first exemplary embodiment of the present invention. However, as a condition for selecting, based on an access frequency, one of n row addresses stored in the row-address storage unit 11 of a corresponding set, the row address selector 23 applies a selection condition that differs from selection conditions employed in other sets.

For example, the row address selector 23 in one of the m sets may apply a specific low frequency condition (e.g., an access-frequency is minimal) as the selection condition, while the row address selectors 23 in other sets may apply specific selection conditions (e.g., an access frequency is maximum).

The intensive access detector 25 is configured substantially similarly to the intensive access detector 15 in the first exemplary embodiment of the present invention. The intensive access detector 25 detects, in each set, a row address, the number of accesses to which reaches the allowable number of accesses. For example, the intensive access detector 25 may issue a refresh to an adjoining row address of the detected row address.

An operation of the access count device 20 configured as described above is described hereinafter.

First, a reset operation in each refresh interval of the access count device 20 is described. Each of the reset controllers 14 of the m sets operates similarly to the reset controller of the first exemplary embodiment of the present invention in steps S1 to S2 illustrated in FIG. 3. This operation causes the access count device 20 to reset each of the row-address storage units 11 and the counters 12 of the m sets at each elapse of a time-period of the refresh interval.

Next, a row-address storage operation of the access count device 20 is described hereinafter.

First, when a row address specified in an access to a memory cell is input to the access count device 20, the row address is input to each of the row-address storage units 11 of the m sets.

Then, the row-address storage unit 11, the counter 12, the row address selector 23, and the reset controller 14 of each set operate substantially similarly to those of the first exemplary embodiment operating in steps S11 to S18 illustrated in FIG. 4. However, in step S16, the row address selector 23 of each set selects one of the n row addresses using the selection condition differing from selection conditions used by the row address selectors 23 of other sets.

Next, an intensive-access detection operation of the access count device 20 is described hereinafter.

First, the intensive access detector 25 detects a row address, the number of accesses to which reaches the allowable number of accesses, in one of the sets (steps S31 to S32 illustrated in FIG. 5). And, the intensive access detector 25 may issue a refresh command to an adjoining row address of the detected row address. Then, the reset controller 14 of the set, in which the row address the number of accesses to which reaches the allowable number of accesses is detected in step S32, operates substantially similarly to that of the first exemplary embodiment of the present invention in steps S33 to S34. This operation results in resetting the corresponding row address and the corresponding access frequency in the row-address storage unit 11 and the counter 12 of the set, respectively.

Thus, description of the operations of the access count device 20 ends.

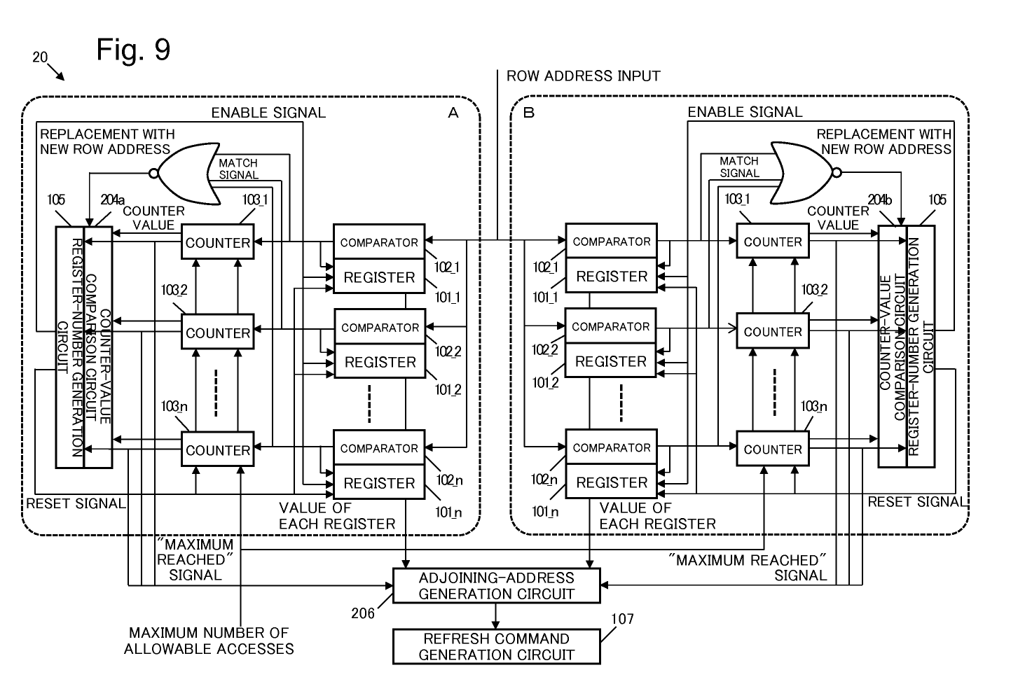

Next, FIG. 9 illustrates an example of a mounting configuration of the access count device 20. In FIG. 9, it is assumed that m=2.

In FIG. 9, the access count device 20 includes 2 sets of a combination of registers 101_1 to 101_n, comparators 102_1 to 102_n, counters 103_1 to 103_n, a counter-value comparison circuit 204, and a register-number generation circuit 105. Moreover, the access count device 20 includes an adjoining-address generation circuit 206, and a refresh-command generation circuit 107. Hereinafter, one of the sets is described as a group A, while the other group is described as a group B. Further, the counter-value comparison circuit 204 included in the group A is described also as a counter-value comparison circuit 204a. Furthermore, the counter-value comparison circuit 204 included in the group B is described also as a counter-value comparison circuit 204b.

When a match/mismatch signal representing a mismatch is input to the counter-value comparison circuit 204a from each of all of the comparators 102_1 to 102_n, the counter-value comparison circuit 204a compares counter values input from the counters 103_1 to 103_n and selects a minimum one of the counter values.

When a match/mismatch signal representing a mismatch is input to the counter-value comparison circuit 204b from each of all of the comparators 102_1 to 102_n, the counter-value comparison circuit 204b compares counter values input from the counters 103_1 to 103_n and selects a maximum one of the counter values. If there is the counter value representing 0 among the counter values input from the counters 103_1 to 103_n, the counter-value comparison circuit 204b selects the counter value representing 0.

Further, the counter-value comparison circuit 204 of each set outputs, to the register-number generation circuit 105, a selection signal representing a No. “i” of the counter 103_i inputting the selected counter value.

When a “maximum reached” signal is input to the adjoining-address generation circuit 206 from the counter 103_i of the group A or B, the adjoining-address generation circuit 206 uses a row address input from the register 101_i of the corresponding group and calculates an adjoining address of the used row address. Then, the adjoining-address generation circuit 206 outputs the calculated adjoining row address to the refresh-command generation circuit 107.

Each of other elements in the mounting configuration illustrated in FIG. 9 is configured similarly to a corresponding element in the example of the mounting configuration in the first exemplary embodiment of the present invention.

A specific example of an operation of the access count device 20 configured as described above is described hereinafter. It is assumed that no row address is stored in each of the registers 101_1 to 101_n of the groups A and B at the start of the following specific operations.

First, when row addresses 1 to n are sequentially input to the access count device 20, the registers 101_2 to 101_n of the groups A and B operate substantially similarly to the registers of the specific example in the first exemplary embodiment of the present invention. Thus, the registers 101_2 to 101_n store the row addresses 2 to n, respectively. Further, the counters 103_2 to 103_n of the groups A and B store a counter value of 1.

Then, when any of the row addresses 1 to n are serially input to the groups A and B, in the access count device 20, the groups A and B operate substantially similarly to the specific example in the first exemplary embodiment of the present invention. This operation causes each of the counters 103_1 to 103_n to count up the counter value thereof.

Next, it is assumed that a row address_new other than the row addresses 1 to n is input to the access count device 20.

At that time, in the group A, none of the comparators 102_1 to 102_n store the row address_new. Therefore, each of the comparators 102_1 to 102_n outputs a match/mismatch signal representing a mismatch. And the counter-value comparison circuit 204a compares counter values input from the counters 103_1 to 103_n and selects a minimum one of the counter values. The counter-value comparison circuit 204a is assumed to select a counter 103_x1 (1≦x1≦n) having the minimum counter value. Then, the register-number generation circuit 105 outputs an enable signal to the register 101_x1 and also outputs a reset signal to the counter 103_x1. The output of the enable signal and the reset signal causes the register 101_x1 to store the row address_new by replacing the row address x1 with the row address_new (step S14). Further, the counter 103_x1 sets to 1 the counter value thereof, which is reset to 0, by counting up by 1, based on a match/mismatch signal which is output from the comparator 102_x1 and represents a match.

Further, at that time, in the group B, none of the comparators 102_1 to 102_n store the row address_new. Thus, each of the comparators 102_1 to 102_n outputs a match/mismatch signal representing a mismatch. And the counter-value comparison circuit 204b compares counter values input from the counters 103_1 to 103_n and selects a maximum one of the counter values. The counter-value comparison circuit 204a is assumed to select a counter 103_x2 (1≦x2≦n) having the maximum counter value. Then, the register-number generation circuit 105 outputs an enable signal to the register 101_x2 and also outputs a reset signal to the counter 103_x2. The output of the enable signal causes the register 101_x2 to store the row address_new by replacing a row address x2 with the row address_new (step S14). Further, the counter 103_x2 sets to 1 the counter value thereof, which is reset to 0, by counting up by 1, based on a match/mismatch signal which is output from the comparator 102_x2 and represents a match.

The above operation is repeated. Thus, the n registers 101 of each of the groups A and B store n row addresses of a corresponding one of different combinations.

Further, it is assumed that in the group A, the counter value of a counter 103_y1 (1≦y1≦n) reaches the allowable number of accesses. Then, the counter 103_y1 outputs a “maximum reached” signal to the register-number generation circuit 105 and the adjoining-address generation circuit 206.

Because the “maximum reached” signal is input to the adjoining-address generation circuit 206 from the counter 103_y1 of the group A, the adjoining-address generation circuit 206 calculates an adjoining row address of a row address input from the register 101_y1 of this group. Then, the adjoining-address generation circuit 206 outputs the calculated adjoining row address to the refresh-command generation circuit 107.

Further, the refresh-command generation circuit 107 generates a refresh command to the input adjoining row address.

Moreover, because the “maximum reached” signal is input to the register-number generation circuit 105 from the counter 103_y1 of the group A, the register-number generation circuit 105 outputs a reset signal to each of the corresponding registers 101_y1 and the corresponding counter 103_y1 of this group. This output causes the register 101_y1 to be empty. Further, due to this output, the counter value of the counter 103_y1 becomes 0.

Thus, description of the example of the mounting configuration and the specific example of the operation of the access count device 20 ends.

Next, advantageous effects of the second exemplary embodiment of the present invention are described hereinafter.

The access count device configured as the second exemplary embodiment of the present invention can count the number of accesses to row addresses with a smaller circuit scale. Consequently, the present exemplary embodiment can enhance accuracy of detecting a row address on which accesses are concentrated in a refresh interval, in a semiconductor memory with a smaller circuit scale and without increasing power consumption and reducing access performance.

The reasons are as follows. In other words, the second exemplary embodiment includes m sets (m is an integer equal to or more than 2) of a combination of the row-address storage unit, the counter, the row address selector, and the reset controller, which are configured substantially similarly to those of the first exemplary embodiment of the present invention, respectively. Further, a row address specified in a memory access is stored in the row-address storage unit of each set. Furthermore, the row address selector of each set selects one of the n row addresses, based on the access frequencies, when an access occurs, which specifies a new row address other than the n row addresses stored in the row-address storage unit of this set. The row address selector of each set applies, as a condition for this selection, a selection condition differing from selection conditions used in other sets. The intensive access detector detects a row address, the access frequency to which reaches the allowable number of accesses, in each set.

Consequently, even in a case where an access specifying a new row address frequently occurs in a state in which the row-address storage unit stores n row addresses (i.e., the n registers is filled with row addresses), the second exemplary embodiment can efficiently count an access frequency to each row address having a high possibility of concentrating accesses thereon. The present exemplary embodiment can implement this configuration with a far smaller circuit scale than a circuit scale needed to provide counter circuits of the number of row addresses in the access count device.

In the second exemplary embodiment of the present invention, the example in the case of m=2 has mainly been described. However, this example does not limit the number of combinations of the row-address storage unit, the counter, the row address selector, and the reset controller.

Further, in the above description of the specific example of the operation of each exemplary embodiment of the present invention, the example of sequentially inputting row addresses 1 to n has been described. However, a chronological-order and a frequency of generation of row addresses input in each exemplary embodiment are not limited to those described in this example.

Furthermore, in each of the above exemplary embodiments of the present invention, the low frequency condition and the high frequency condition have been exemplified as the selection condition applied by the row address selector. However, the selection condition applied by the row address selector may be other conditions for selecting one of the n row addresses, based on the access frequency.

Moreover, in each of the above exemplary embodiments of the present invention, the example of issuing a refresh to the adjoining row address of the row address detected by the intensive access detector has mainly been described. Processing performed by the intensive access detector of each exemplary embodiment is not limited thereto. The intensive access detector of each exemplary embodiment may perform other types of processing based on the detected row address. Further, each exemplary embodiment may be configured to output the detected row address to other units which perform processing on the row address on which accesses are concentrated, in a semiconductor memory.

### Third Exemplary Embodiment

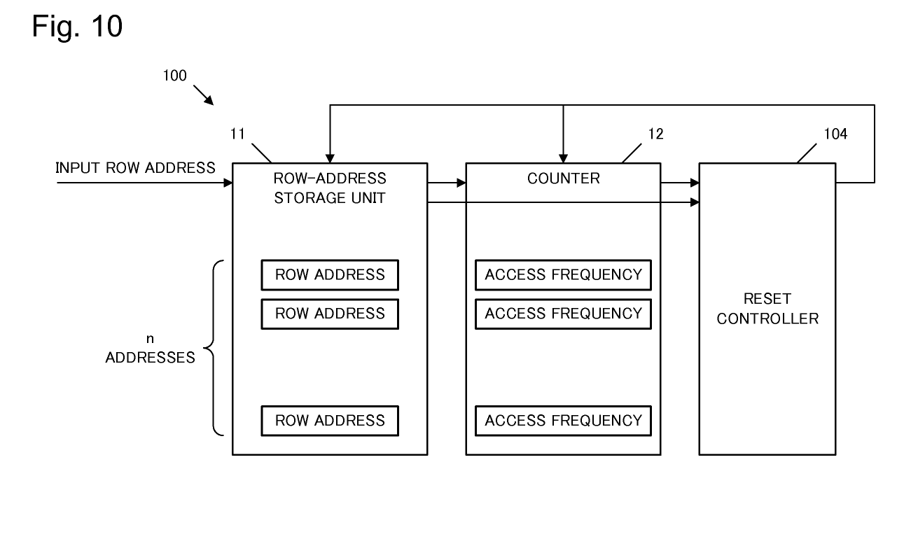

Next, an access count device 100 according to a third exemplary embodiment of the present invention is described hereinafter with reference to FIG. 10.

FIG. 10 is a diagram illustrating an example of a minimum configuration of the access count device according to the third exemplary embodiment of the present invention. In FIG. 10, the access count device 100 includes a row-address storage unit 11, a counter 12, and a reset controller 104.

The row-address storage unit 11 and the counter 12 are configured similarly to the row-address storage unit 11 and the counter 12 described in the first and second exemplary embodiments of the present invention, respectively.

The reset controller 104 notifies the row-address storage unit 11 to replace one of the n row addresses stored in the row address storage unit 11 with a new row address or to discard one of such n row addresses. For example, it is advisable that the reset controller 104 selects a row address, whose degree of importance as a target of access-counting can be determined to be lower than degrees of importance of other row addresses, as a row address to be replaced with a new row address or to be discarded. Then, the reset controller 104 notifies the counter 12 to reset the access frequency to the row address replaced or discarded.

With such a configuration, the access count device 100 according to the third exemplary embodiment of the present invention does not need to provide counter circuits of the number of row addresses in the counter. The access count device 100 only needs to provide n counter circuits in the counter. Consequently, the access count device 100 can efficiently count the number of accesses to a row address, whose degree of importance as a target of access-counting is high, among the n row addresses.

Thus, according to the third exemplary embodiment of the present invention, accesses to a row address in a semiconductor memory can be counted with a smaller circuit scale.

In each of the above exemplary embodiments of the present invention, the access count device may be implemented in either a semiconductor memory or a CPU (Central Processing Unit) or a semiconductor memory controller integrated circuit. Further, the respective functional blocks of the access count device may be implemented by being dispersively distributed in a plurality of devices such as a semiconductor memory device, a CPU, and a semiconductor memory controller.

Furthermore, the respective above exemplary embodiments may be carried out by being appropriately combined with one another.

Moreover, the present invention is not limited to the respective above exemplary embodiments. The present invention may be carried out in various modes.

Further, a part or all of the respective above exemplary embodiments may be also described in the following supplementary notes. However, the present invention is not limited to the following supplemental notes.

(Supplementary Note 1)

An access count device including:

a row-address storage unit that stores up to a specific number n (n is an integer equal to or more than 1) of row addresses specified in accesses to memory cells;

a count unit that counts an access frequency to each row address stored in the row-address storage unit; and

a reset control unit that notifies the row-address storage unit to replace one of the n row addresses with a new row address or discard one of the n row addresses, and also that notifies the count unit to reset an access frequency to the row address replaced or discarded.

(Supplementary Note 2)

An access count device according to supplementary note 1, further including a row address selection unit that selects one of the n row addresses, based on the access frequency, if an access occurs, which specifies a new row address other than the n row addresses stored in the row-address storage unit,

wherein the reset control unit notifies the row-address storage unit to store the new row address by replacing a row address selected by the row address selection unit with the new row address, and also that notifies the count unit to reset an access frequency to the replaced row address.

(Supplementary Note 3)

An access count device according to supplementary note 1 or supplementary note 2, wherein the reset control unit notifies the count unit to discard the row address, the access frequency to which reaches a specific allowable number of accesses, and also notifies the count unit to reset the access frequency to the discarded row address.

(Supplementary Note 4)

An access count device according to supplementary note 2 or supplementary note 3, wherein the row address selection unit selects one of the n row addresses, the access frequency to the selected one of the n row addresses meeting a specific low frequency condition.

(Supplementary Note 5)

An access count device according to one of supplementary note 2 to supplementary note 4, including m sets (m is an integer equal to or more than 2) of a combination of the row-address storage unit, the count unit, the row address selection unit, and the reset control unit,

wherein a row address specified in the access is stored in the row-address storage unit of each set, and

wherein the row address selection unit of each set applies a selection condition differing from selection conditions applied by other sets, as a selection condition for selecting one of the n row addresses, based on the access frequency, if an access occurs, which specifies a new row address other than the n row addresses stored in the row-address storage unit of a same set as the set in which the row address selection unit applies the selection condition.

(Supplementary Note 6)

An access count device according to supplementary note 5, wherein the row address selection unit of one of the m sets applies a specific low frequency condition as the selection condition, and wherein the row address selection unit of each set other than the one of the m sets applies a specific high frequency condition as the selection condition.

(Supplementary Note 7)

An access count device according to one of supplementary note 1 to supplementary note 6, wherein the n is a value based on a refresh interval, an access cycle and the allowable number of accesses.

(Supplementary Note 8)

An access count device according to one of supplementary note 1 to supplementary note 7, further including an intensive access detection unit that detects a row address the access frequency to which reaches the allowable number of accesses.

(Supplementary Note 9)

An access count device according to supplementary note 8, wherein the intensive access detection unit issues a refresh to an adjoining row address of the detected row address.

(Supplementary Note 10)

A memory system including:

an access count device according to one of supplementary note 1 to supplementary note 9; and

a memory cell array including the memory cells.

(Supplementary Note 11)

An access count method including:

storing up to a specific number n (n is an integer equal to or more than 1) of row addresses specified in accesses to memory cells;

counting an access frequency to each of the stored row addresses;

replacing one of the n row addresses with a new row address or discarding the one of the n row addresses; and

resetting the access frequency to the row address replaced or discarded.

The previous description of embodiments is provided to enable a person skilled in the art to make and use the present invention. Moreover, various modifications to these exemplary embodiments will be readily apparent to those skilled in the art, and the generic principles and specific examples defined herein may be applied to other embodiments without the use of inventive faculty. Therefore, the present invention is not intended to be limited to the exemplary embodiments described herein but is to be accorded the widest scope as defined by the limitations of the claims and equivalents.

Further, it is noted that the inventor's intent is to retain all equivalents of the claimed invention even if the claims are amended during prosecution.

### Reference Signs List

1, 2 Memory systems
10, 20 Access count devices
30 Memory cell array
11 Row-address storage unit
12 Counter
13, 23 Row address selector
14 Reset controller
15, 25 Intensive access detector
101 Register
102 Comparator
103 Counter
104, 204 Counter-value comparison circuits
105 Register-number generation circuit
106, 206 Adjoining-address generation circuits
107 Refresh-command generation circuit

1. An access count device comprising:
a row-address storage unit that stores up to a specific number n (n is an integer equal to or more than 1) of row addresses specified in accesses to memory cells;
a counter that counts an access frequency to each row address stored in the row-address storage unit; and
a reset controller that notifies the row-address storage unit to replace one of the n row addresses with a new row address or discard one of the n row addresses, and also that notifies the counter to reset an access frequency to the row address replaced or discarded.

2. The access count device according to claim 1, further comprising
a row address selector that selects one of the n row addresses, based on the access frequency, if an access occurs, which specifies a new row address other than the n row addresses stored in the row-address storage unit,
wherein the reset controller notifies the row-address storage unit to store the new row address by replacing the row address selected by the row address selector with the new row address, and also that notifies the counter to reset an access frequency to the replaced row address.

3. The access count device according to claim 1, wherein the reset controller notifies the row address storage unit to discard a row address the access frequency to which reaches a specific allowable number of accesses, and also notifies the counter to reset the access frequency to the discarded row address.

4. The access count device according to claim 2, wherein the row address selector selects one of the n row addresses the access frequency to the one of the n row addresses meets a specific low frequency condition.

5. The access count device according to claim 2, further comprising m sets (m is an integer equal to or more than 2) of a combination of the row-address storage unit, the counter, the row address selector, and the reset controller, wherein the row addresses specified in the accesses are stored in the row-address storage unit of each set, and
wherein the row address selector in each set applies a selection condition differing from selection conditions applied by other sets, as a selection condition for selecting one of the n row addresses, based on the access frequency, if an access occurs, which specifies a new row address other than the n row addresses stored in the row-address storage unit in a same set as the set in which the row address selector applies the selection condition.

6. The access count device according to claim 5, wherein the row address selector in one of the m sets applies a specific low frequency condition as the selection condition, and wherein the row address selector in each of other sets applies a specific high frequency condition as the selection condition.

7. The access count device according to claim 1, wherein the n is a value based on a refresh interval, an access cycle, and the allowable number of accesses.

8. The access count device according to claim 1, further comprising an intensive access detector that detects a row address the access frequency to which reaches the allowable number of accesses.

9. A memory system comprising:
an access count device according to claim 1; and
a memory cell including the memory cells.

10. An access count method comprising:
storing up to a specific number n (n is an integer equal to or more than 1) of row addresses specified in accesses to memory cells;
counting an access frequency to each of the stored row addresses;
replacing one of the n row addresses with a new row address or discarding the one of the n row addresses; and
resetting the access frequency to the row address replaced or discarded.
